(19) United States
(12) Patent Application Publication
(10) Pub. No.: US 2026/0231339 A1
(43) Pub. Date: Aug. 6, 2026

(54) METHOD FOR MANUFACTURING INTEGRATED POWER ELECTRONICS

(71) Applicant: Toyota Motor Engineering & Manufacturing North America, Inc., Plano, TX (US)

(72) Inventors: Feng Zhou, Ann Arbor, MI (US); Tianzhu Fan, Houston, TX (US); Shailesh N. Joshi, Ann Arbor, MI (US); Ercan M. Dede, Ann Arbor, MI (US)

(73) Assignee: Toyota Motor Engineering & Manufacturing North America, Inc., Plano, TX (US)

(21) Appl. No.: 19/041,300

(22) Filed: Jan. 30, 2025

(51) Int. Cl. H05K 3/00; H05K 3/30; H05K 3/40

(52) U.S. Cl. CPC H05K 3/0064; H05K 3/0032; H05K 3/0047; H05K 3/301; H05K 3/4076; H05K 2203/0228; H05K 2203/0235; H05K 2203/0723; H05K 2203/107

(57) ABSTRACT

A method for manufacturing an integrated power electronics (IPEs) embedded printed circuit board (PCB) assembly may include providing a dielectric panel having a first plurality of openings configured to receive power devices and a second plurality of openings configured to receive thermal slugs. The method may include inserting power devices into the first plurality of openings and thermal slugs into the second plurality of openings. The method may include securing a multi-layer printed circuit board (PCB) structure to the dielectric panel having the inserted power devices and thermal slugs. The method may include securing a cold plate panel to the dielectric panel opposite the multi-later PCB structure to form an integrated power electronics fabrication panel.

### TECHNICAL FIELD

The present specification generally relates to integrated power electronics and, more specifically, to a method for manufacturing integrated power electronics with thermal slugs for controlling a temperature of the integrated power electronics.

### BACKGROUND

Printed circuit boards (PCBs) are typically used for mechanical support and electrical connection of electronic components using conductive pathways of copper sheets laminated onto a non-conductive substrate. Multi-layer PCBs provide higher capacity and/or density of electronic components in a smaller footprint by incorporating two or more layers. Power devices may be attached to the PCBs. However, power devices may generate heat during operation.

The present disclosure addresses issues related to heat dissipation and the manufacture of multi-layer PCBs with power devices.

### SUMMARY

In one embodiment, a method for manufacturing an integrated power electronics (IPEs) embedded within a printed circuit board (PCB) assembly includes fabricating a dielectric panel that includes a plurality of openings sized and shaped to receive at least one power device and a plurality of thermal slugs, the at least one power device is embedded within the dielectric panel. The method includes laminating a multi-layer printed circuit board on the dielectric panel having the at least one power device embedded within the dielectric panel layer-by-layer, and laser drilling and electroplating layers of the multi-layer printed circuit board to create a plurality of copper vias between the layers. The method includes bonding the dielectric panel and the multi-layer printed circuit board to a cold plate panel to form an integrated power electronics fabrication panel. The method includes cutting or separating the integrated power electronics fabrication panel into a PCB cold plate assembly. The method includes drilling an inlet port and an outlet port through each cold plate into an internal fluid chamber of the cold plate.

In another embodiment, a method for manufacturing an integrated power electronics (IPEs) embedded within a printed circuit board (PCB) assembly may include providing a dielectric panel having a first plurality of openings configured to receive power devices and a second plurality of openings configured to receive thermal slugs. The method may include inserting power devices into the first plurality of openings and thermal slugs into the second plurality of openings. The method may include securing a multi-layer printed circuit board (PCB) structure to the dielectric panel having the inserted power devices and thermal slugs. The method may include securing a cold plate panel to the dielectric panel opposite the multi-later PCB structure to form an integrated power electronics fabrication panel.

In yet another embodiment, a method for manufacturing an integrated power electronics (IPEs) embedded within a printed circuit board (PCB) assembly includes providing a dielectric panel having a first plurality of openings configured to receive power devices and a second plurality of openings configured to receive thermal slugs. The method includes inserting power devices into the first plurality of openings and thermal slugs into the second plurality of openings, the thermal slugs being formed of diamond material or copper material. The method includes securing a multi-layer printed circuit board (PCB) structure to the dielectric panel having the inserted power devices and thermal slugs. The method includes securing a cold plate panel to the dielectric panel opposite the multi-later PCB structure to form an integrated power electronics fabrication panel. The method includes cutting the integrated power electronics fabrication panel into separate single PCB assemblies.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts an integrated power electronics (IPEs) embedded within a printed circuit board (PCB) assembly according to one or more embodiments shown and described herein;

FIG. 2 schematically depicts a top plan view of a dielectric panel with first and second openings for manufacturing the IPE embedded PCB assembly of FIG. 1 prior to cutting into power device layers according to one or more embodiments shown and described herein;

FIG. 3 schematically depicts a cross-section of a portion of the dielectric panel of FIG. 2 taken from line 3-3 and having power devices in the first opening and thermal slugs in the second openings according to one or more embodiments shown and described herein;

FIG. 4 schematically depicts a cross-section of securing a portion of a multi-layer PCB structure to the portion of the dielectric panel of FIG. 3 to from a multi-layer PCB for manufacturing the IPE embedded PCB assembly of FIG. 1 and according to one or more embodiments shown and described herein;

FIG. 5 schematically depicts a perspective view of securing the multi-layer PCB to a cold plate panel to form an integrated power electronics fabrication panel for manufacturing the IPE embedded PCB assembly of FIG. 1 and according to one or more embodiments shown and described herein;

FIG. 6 schematically depicts a top plan view of separating an IPE embedded PCB from the integrated power electronics fabrication panel for manufacturing the IPE embedded PCB assembly of FIG. 1 and according to one or more embodiments shown and described herein;

FIG. 7 schematically depicts a cross-section of the IPE embedded PCB of FIG. 6 taken along a line 7-7 with ports drilled into a cold plate of the IPE embedded PCB according to one or more embodiments shown and described herein; and

FIG. 8 schematically depicts a cross-section of the IPE embedded PCB with tube attached at the ports drilled into the cold plate of FIG. 1 taken along a line 8-8 according to one or more embodiments shown and described herein.

### DETAILED DESCRIPTION

Embodiments described herein are directed to a method for manufacturing an integrated power electronics (IPEs) embedded printed circuit board (PCB) assembly. The method includes fabricating a dielectric panel that includes a plurality of openings sized and shaped to receive at least one power device and a plurality of thermal slugs, with the at least one power device is embedded within the dielectric panel. The method includes laminating, bonding, and/or otherwise securing, a multi-layer printed circuit board and a cold plate panel to the dielectric panel having the plurality of openings with at least one power device is embedded therein to form an integrated power electronics fabrication panel. The integrated power electronics fabrication panel can be cut or otherwise separated into individual PCB cold plate assemblies. Attaching, e.g., laminating, the multi-layer printed circuit board to the dielectric panel with the at least one power device embedded therein may provide increase manufacturing efficiencies and overall reduced costs, e.g., as compared to conventional manufacturing methods.

Various embodiments of the method for manufacturing an integrated power electronics (IPEs) embedded printed circuit board (PCB) assembly are described in more detail herein. Whenever possible, the same reference numerals will be used throughout the drawings to refer to the same or like parts.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

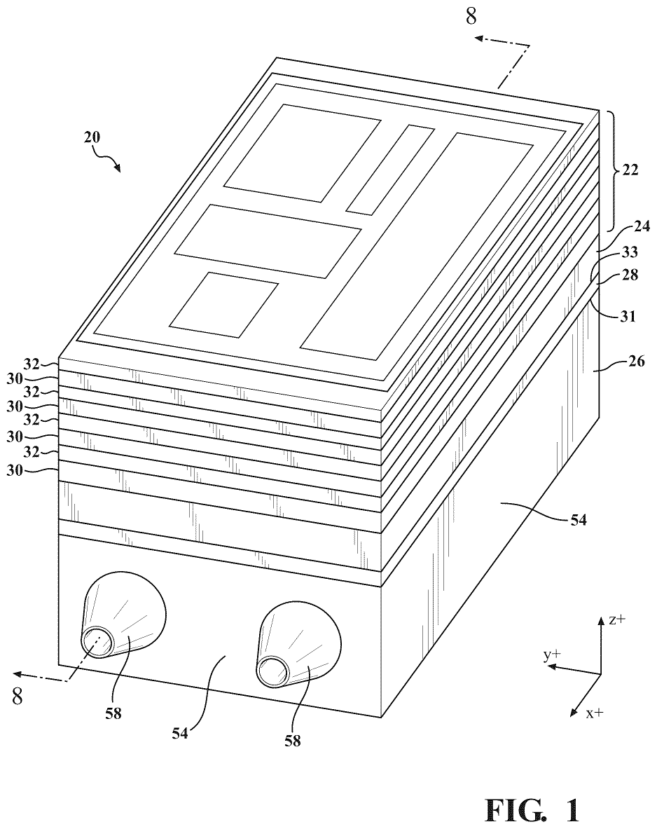

Directional terms as used herein—for example up, down, right, left, front, back, top, bottom—are made only with reference to the figures as drawn and are not intended to imply absolute orientation. As used herein, the term “system vertical direction” refers to the refers to the upward-downward direction of the system (i.e., in the +/−Z direction of the coordinate axes depicted in FIG. 1). As used herein, “upper” is defined as generally being towards the positive Z direction of the coordinate axes shown in the drawings. “Lower” or “below” is defined as generally being towards the negative Z direction of the coordinate axes shown in the drawings.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

Now referring to FIGS. 1 and 8, an example integrated power electronics (IPEs) embedded printed circuit board (PCB) assembly 20 is schematically depicted according to an example embodiment shown and described herein. The PCB assembly 20 may include a multi-layer PCB 22 and a power device layer 24. The example PCB assembly 20 may also include a cold plate 26 and a bonding interface 28 between the power device layer 24 and the cold plate 26.

The multi-layer PCB 22 may include two or more semiconductors, control/drive/protection electronic circuitry, and/or passive components, embedded therein. The multi-layer PCB 22 may include a plurality of dielectric layers 30 and a plurality of power layers 32. The power layers 32 may include a dielectric material and a conductive material. The dielectric layers 30 include the dielectric material and conductive vias that provide electrical communication or pathways between adjacent power layers 32. Stated differently, the power layers 32 include conductive (e.g., copper) patterns and the dielectric layers 30 include conductive (e.g., copper) pathways that connect the conductive patterns such that the multi-layer PCB 22 functions and/or operates as desired.

In some embodiments, the plurality of power layers 32 are formed from a glass reinforced epoxy laminate dielectric material (e.g., FR-4), or other dielectric material, with the conductive material embedded therein. In other embodiments, the plurality of power layers 32 are manufactured using additive manufacturing techniques and may be manufactured using a dielectric material ink to form the dielectric material, with the conductive material embedded therein. In other embodiments, the conductive material may also be manufactured using additive manufacturing techniques such as with a conductive material ink. Non limiting examples of dielectric material inks are inks that include UV-curable dielectric materials such as UV-curable acrylated monomer selected from one or more of an acrylate epoxy, an acrylate polyester, an acrylate urethane, and an acrylate silicone, among others. And non-limiting examples of conductive material inks are inks that include silver nanoparticles and/or graphene nanosheets, among others. It should be understood that the dielectric layers 30 can also be formed from a glass reinforced epoxy laminate dielectric material (e.g., FR-4), or other dielectric material, or 3D printed using a dielectric material ink, and the like.

As used herein, the terms “additively manufactured” or “additive manufacturing techniques or processes” refer generally to manufacturing processes wherein successive layers of material(s) are provided on each other to “build-up,” layer-by-layer, a three-dimensional component. The successive layers generally fuse together to form a monolithic component which may have a variety of integral sub-components. Although additive manufacturing technology is described herein as enabling fabrication of complex objects by building objects point-by-point, layer-by-layer, typically in a vertical direction, other methods of fabrication are possible and within the scope of the present subject matter. For example, although the discussion herein refers to the addition of material to form successive layers, one skilled in the art will appreciate that the methods and structures disclosed herein may be practiced with any additive manufacturing technique or manufacturing technology. For example, embodiments of the present invention may use layer-additive processes, layer-subtractive processes, or hybrid processes.

Suitable additive manufacturing techniques in accordance with the present disclosure may include, for example and without limitation, Fused Deposition Modeling (FDM), Selective Laser Sintering (SLS), 3D printing such as by inkjets and laserjets, Sterolithography (SLA), Direct Selective Laser Sintering (DSLS), Electron Beam Sintering (EBS), Electron Beam Melting (EBM), Laser Engineered Net Shaping (LENS), Laser Net Shape Manufacturing (LNSM), Direct Metal Deposition (DMD), Digital Light Processing (DLP), Direct Selective Laser Melting (DSLM), Selective Laser Melting (SLM), Direct Metal Laser Melting (DMLM), and other known processes.

The additive manufacturing processes described herein may be used for forming components using any suitable material. For example, the material may be plastic, metal, concrete, ceramic, polymer, epoxy, photopolymer resin, or any other suitable material that may be in solid, liquid, powder, sheet material, wire, or any other suitable form. More specifically, according to exemplary embodiments of the present subject matter, the additively manufactured components described herein may be formed in part, in whole, or in some combination of materials including but not limited to pure metals, nickel alloys, chrome alloys, titanium, titanium alloys, magnesium, magnesium alloys, aluminum, aluminum alloys, and nickel or cobalt base superalloys (e.g., those available under the name Inconel® available from Special Metals Corporation). These materials are examples of materials suitable for use in the additive manufacturing processes described herein, and may be generally referred to as “additive materials.”

In addition, one skilled in the art will appreciate that a variety of materials and methods for bonding those materials may be used and are contemplated as within the scope of the present disclosure. As used herein, references to “fusing” may refer to any suitable process for creating a bonded layer of any of the above materials. For example, if an object is made from polymer, fusing may refer to creating a thermoset bond between polymer materials. If the object is epoxy, the bond may be formed by a crosslinking process. If the material is ceramic, the bond may be formed by a sintering process. If the material is powdered metal, the bond may be formed by a melting or sintering process. One skilled in the art will appreciate that other methods of fusing materials to make a component by additive manufacturing are possible, and the presently disclosed subject matter may be practiced with those methods.

In addition, the additive manufacturing process disclosed herein allows a single component to be formed from multiple materials. Thus, the components described herein may be formed from any suitable mixtures of the above materials. For example, a component may include multiple layers, segments, or parts that are formed using different materials, processes, and/or on different additive manufacturing machines. In this manner, components may be constructed which have different materials and material properties for meeting the demands of any particular application. In addition, although the components described herein are constructed entirely by additive manufacturing processes, it should be appreciated that in alternate embodiments, all or a portion of these components may be formed via casting, machining, and/or any other suitable manufacturing process. Indeed, any suitable combination of materials and manufacturing methods may be used to form these components.

An exemplary additive manufacturing process will now be described. Additive manufacturing processes fabricate components using three-dimensional (3D) information, for example a three-dimensional computer model, of the component. Accordingly, a three-dimensional design model of the component may be defined prior to manufacturing. In this regard, a model or prototype of the component may be scanned to determine the three-dimensional information of the component. As another example, a model of the component may be constructed using a suitable computer aided design (CAD) program to define the three-dimensional design model of the component.

The design model may include 3D numeric coordinates of the entire configuration of the component including both external and internal surfaces of the component. For example, the design model may define the body, the surface, and/or internal passageways such as openings, support structures, and the like. In one exemplary embodiment, the three-dimensional design model is converted into a plurality of slices or segments, e.g., along a central (e.g., vertical) axis of the component or any other suitable axis. Each slice may define a thin cross section of the component for a predetermined height of the slice. The plurality of successive cross-sectional slices together form the 3D component. The component is then “built-up” slice-by-slice, or layer-by-layer, until finished.

In this manner, the components described herein may be fabricated using the additive process, or more specifically each layer is successively formed, e.g., by fusing or polymerizing a plastic using laser energy or heat or by sintering or melting metal powder. For example, a particular type of additive manufacturing process may use an energy beam, for example, an electron beam or electromagnetic radiation such as a laser beam, to sinter or melt a powder material. Any suitable laser and laser parameters may be used, including considerations with respect to power, laser beam spot size, and scanning velocity. The build material may be formed by any suitable powder or material selected for enhanced strength, durability, and useful life, particularly at high temperatures.

Still referring to FIGS. 1 and 8, the plurality of dielectric layers 30 and the plurality of power layers 32 have a predefined average thickness (z-direction). For example, and without limitation, in some variations, the predefined average thickness is between about 50 micrometers (μm) and about 250 μm, for example, between about 75 μm and about 200 μm. And in at least one variation, the predefined thickness is between about 75 μm and about 150 μm, for example, between about 80 μm and about 120 μm. The multi-layer PCB 22 is bonded to the power device layer 24, as further discussed below.

The power device layer 24 includes a dielectric frame 34. The dielectric frame 34 may be a glass reinforced epoxy laminate dielectric material (e.g., FR-4), or other dielectric material.

The dielectric frame 34 of the power device layer 24 may include a first plurality of openings 36 configured to receive power devices 38. In other words, the first plurality of openings 36 are sized and shaped to receive the power devices 38 therein, (e.g., with one power device 38 disposed in each opening 36 of the first plurality of openings 36). Power devices 38 may be semiconductor devices used as a switch or rectifier. For example, and without limitation, in some variations, the power device 38 may include a metal-oxide-semiconductor field-effect transistor (MOSFET), an Insulated-gate bipolar transistor (IGBT), and/or the like. The power device 38 may be positioned on a copper-graphite substrate with a graphite core embedded within a shell of copper. The copper-graphite substrate may be bonded to the copper shell, (e.g., via silver sintering).

The dielectric frame 34 of the power device layer 24 may include a second plurality of openings 40 configured to receive thermal slugs 42. In other words, the second plurality of openings 40 are sized and shaped to receive the thermal slugs 42 therein, (e.g., with one thermal slug 42 disposed is each opening 40 of the second plurality of openings 40). The thermal slugs 42 provide thermal conduits. For example, and without limitation, the thermal conducts defined by the thermal slugs 42 may be configured to receive and/or direct heat energy from the multi-layer PCB 22 and the power device layer 24 to the cold plate 26. The thermal slugs 42 may be in thermal communication with components of the multi-layer PCB 22. The thermal slugs 42 may be formed of a material having a generally high thermal conductivity. For example, and without limitation, a material having a thermal conductivity greater than 100 W/mK. High thermal conductivity may also be referred to as low thermal resistance (LTR). For example, and without limitation, in some variations, the thermal slugs 42 may be copper. The thermal slugs 42 may be formed of a material having a generally high thermal conductivity and a generally low electrical conductivity, (i.e., an electrical insulator). For example, the thermal slugs 42 may be formed of diamond material. Use of an electronic insulator material for the thermal slugs 42 may permit a wider variety of materials to be used with the bonding interface 28, as discussed below.

The cold plate 26 may be included in the PCB assembly 20 and may be configured to remove heat energy generated from, for example, and without limitation, in some variations, components of the power device layer 24 and the multi-layer PCB 22. The power device layer 24 may be bonded to the cold plate 26 such that the power devices 38 and the thermal slugs 42 are in thermal communication with the cold plate 26. Accordingly, and during operation of the integrated power electronics embedded PCB assembly 20, the power devices 38 and other components are cooled via the flow of heat from the power devices 38 and the thermal slugs 42 to the cold plate 26.

In some variations, the cold plate 26 may include an internal fluid chamber 44. Each fluid chamber 44 may be defined by a top wall 50, a bottom wall 52, and sidewalls 54 extending from the top wall 50 to the bottom wall 52. The cold plate 26 may include an inlet port 46 and an outlet port 48, e.g., extending through sidewalls 54 of the cold plate 26. In some variations, the internal fluid chamber 44 may include at least one heat sink 56. The at least one heat sink 56 is configured to increase an amount of surface area in contact with fluid in the internal fluid chamber 44. For example, and without limitation, in some variations, fins, porous material, mesh-structured, machined and/or cast at least one heat sink 56 may be disposed within the fluid chamber 44. In at least one variation, an inlet tube 58 is attached to and in fluid communication with the inlet port 46 and/or an outlet tube 60 is attached to and in fluid communication with the outlet port 48. The cold plate 26 is formed of a material having a generally high thermal conductivity. Example materials include, without limitation, aluminum, copper, and/or the like.

The bonding interface 28 may be included in the PCB assembly 20 and may be configured to secure the cold plate 26 to the power device layer 24. In some variations, the bonding interface 28 may include a LTR dielectric layer disposed between the power device layer 24 and the cold plate 26. In other variations, the bonding interface 28 may include a chemical vapor deposition (CVD) dielectric layer disposed between the power device layer 24 and the cold plate 26. In still other variations, the bonding interface 28 may include a ceramic sintered layer disposed between the power device layer 24 and the cold plate 26. In other variations, the bonding interface 28 may include a solder layer, solder-AlN-solder layers, and/or solder-Si3N4-solder layers. And in at least one variation the bonding interface 28 is one or more 3D printed dielectric layers disposed between the power device layer 24 and the cold plate 26, e.g., one or more polymer-conductive filler composite layers.

In some variations, the bonding interface 28 may be disposed between an upper surface 31 of the cold plate 26 in the system vertical direction (i.e., in the +Z direction) and a lower surface 33 of the power device layer 24 in the system vertical direction (i.e., in the −Z direction). For example, in some variations, the bonding interface 28 is bonded directly to the upper surface 31 of the cold plate 26 such that the bonding interface 28 is in direct contact with the upper surface 31. In at least one variation, the bonding interface 28 is bonded directly to the lower surface 33 the power device layer 24. And in some variations, the bonding interface 28 is bonded directly to the upper surface 31 of the cold plate 26 and the lower surface 33 the power device layer 24. As used herein, the phrase “directly bonded” refers to one component or layer being bonded to and in direct contact with another component or layer, i.e., without any additional components or layers therebetween.

In variations where the bonding interface 28 includes a LTR dielectric material, the bonding interface 28 can be formed from any dielectric material and/or dielectric composite material suitable to electrically isolate the power device layer 24 from the cold plate 26. In some variations, the LTR dielectric material is a ceramic-polymer composite dielectric material such as BaTiO3-polymer dielectric materials, Pb(ZrxTi1−x)O3-polymer dielectric materials (0≤x≤1), and/or SrTiO3 dielectric materials, among others. Also, in some variations, the LTR dielectric material according to the teachings of the present disclosure may have an average thickness (z direction) less than about 250 μm, for example less than about 200 μm, less than about 150 μm, less than about 100 μm, less than about 50 μm, less than about 40 μm, less than about 30 μm, less than about 20 μm, or less than about 10 μm. In some variations the LTR dielectric layer may have an average thickness between about 10 μm and about 50 μm, for example between about 20 μm and about 40 μm, or between about 25 μm and about 35 μm.

In variations where the bonding interface 28 includes a CVD dielectric layer (not shown), the CVD dielectric layer can be formed or deposited directly on the upper surface 31 of the cold plate 26, and the bonding interface 28 can be in direct contact with and sandwiched between CVD dielectric layer and the lower surface 33 of the power device layer 24. In other variations, the CVD dielectric layer can be formed or deposited directly on the lower surface 33 of the power device layer 24, and the bonding interface 28 can include a bonding layer in direct contact with the upper surface 31 of the cold plate 26. The bonding layer can be formed from any bonding material suitable for electronic circuitry and/or semiconductor component fabrication including tin, lead free solders, bonding material used for transient liquid phase (TLP) bonding, and bonding material used for sintering, among others. Also, the bonding layer can have a thickness between about 50 μm and about 250 μm, for example, between about 50 μm and about 200 μm, between about 50 μm and about 150 μm, or between about 75 μm and about 125 μm.

In some variations, a thin (e.g., less than about 10 or 20 μm) metallization that enhances bonding between the bonding interface 28 and the power device layer 24 and/or the cold plate 26 may be included. For example, in some variations the bonding interface 28 includes the CVD dielectric layer, the LTR dielectric layer, or the ceramic sintered layer, and in such variations a thin metallization layer can be present between the upper surface 31 of the cold plate 26 and the CVD dielectric layer, the LTR dielectric layer, or the ceramic sintered layer, and/or a thin metallization layer can be present between the lower surface 33 of the power device layer 24 and the CVD dielectric layer, the LTR dielectric layer, or the ceramic sintered layer. However, it should be understood that when the bonding interface 28 does not include an electrical insulation layer, e.g., when a copper conductive layer of a multi-layer PCB 22 is bonded directly to the cold plate 26, a metallization layer may not be desired or present. Further, when the thermal slug 42 are a material having a generally low electrical conductivity, e.g., diamond, an electrical insulation layer may be omitted from the bonding interface 28.

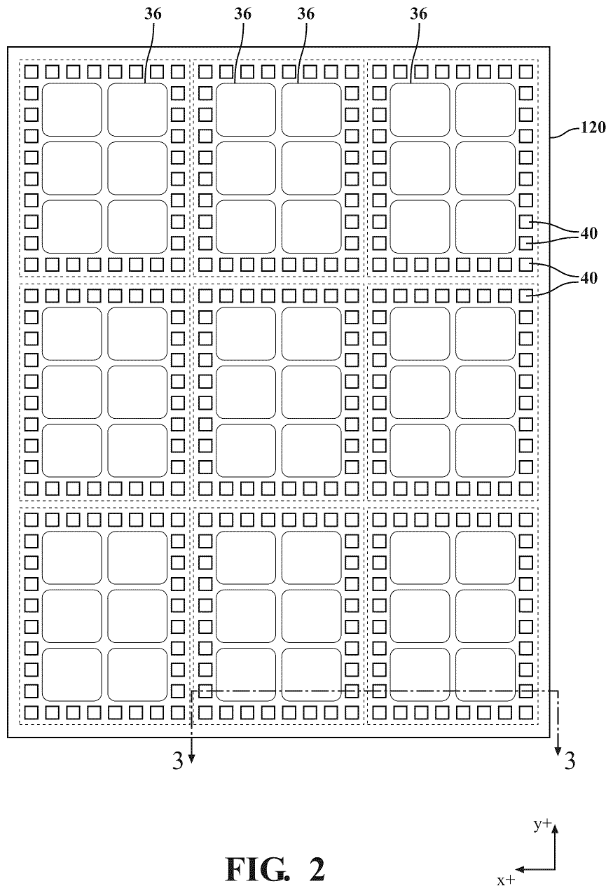

With reference to FIGS. 2-8, method steps for manufacturing a plurality of the PCB assemblies 20 are schematically depicted. The method includes providing a dielectric panel 120 having a first plurality of openings 36 configured to receive power devices 38 and a second plurality of openings 40 configured to receive thermal slugs 42, as best shown in FIG. 2. The dielectric panel 120 may be formed of an FR-4 material. FR-4 is a glass-reinforced epoxy laminate material that includes a woven fiberglass cloth and a flame-retardant epoxy resin binder. The first plurality of openings 36 and the second plurality of openings 40 may be arranged such that the dielectric panel 120 can be cut or otherwise separated into sections, each of the sections providing the dielectric frame 34 of a PCB assembly 20. For example, and without limitation, in some variations, a certain arrangement of first plurality of openings 36 and second plurality of openings 40 can be iteratively provided across the dielectric panel 120, where the certain arrangement of first plurality of openings 36 and second plurality of openings 40 are sized and positioned to receive the power devices 38 and the heat slugs of a power device layer 24 of a single PCB assembly 20.

Providing the dielectric panel 120 having the first plurality of openings 36 configured to receive power devices 38 and the second plurality of openings 40 configured to receive thermal slugs 42 may include fabricating the dielectric panel 120 such that the dielectric panel 120 includes a plurality of openings 36, 40 sized and shaped to receive the one power device 38 and a plurality of thermal slugs 42. Fabricating of the dielectric panel 120 may include machining the first plurality of openings 36 configured to receive power devices 38 and machining the second plurality of openings 40 configured to receive thermal slugs 42 into a panel of dielectric material. The panel of dielectric material may be machined with a mill, waterjet, laser, or with any other suitable tooling. The machining may be done on-site, i.e., at a location were the PCB assemblies 20 will be completed. Alternately, the machining may be done off-site.

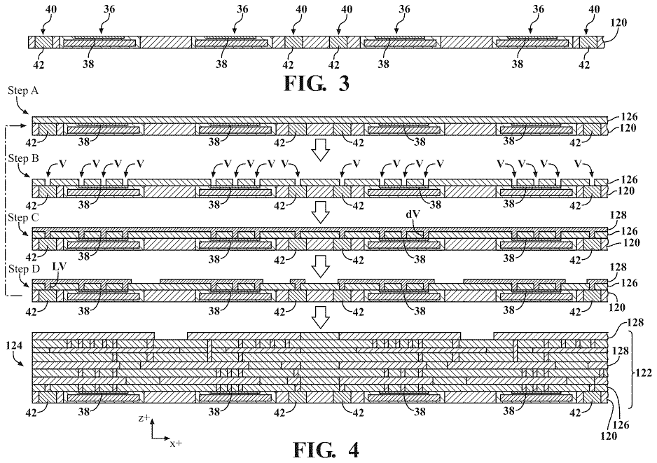

After providing the dielectric panel 120 having first plurality of openings 36 configured to receive power devices 38 and second plurality of openings 40 configured to receive thermal slugs 42, the method includes inserting power devices 38 into the first plurality of openings 36 and thermal slugs 42 into the second plurality of openings 40, as shown in FIG. 3. The power devices 38 and the thermal slugs 42 may by inserted, for example, and without limitation, in some variations, with a pick and place robot or other suitable equipment. The power devices 38 and/or the thermal slugs 42 may be inserted individually, i.e., one at a time. In other embodiments, the power devices 38 and/or the thermal slugs 42 may be inserted in pairs, or in any combination (e.g., one of each of the power devices 38 and the thermal slugs 42, one power device 38 and two or more thermal slugs, two or more power devices 38 and one thermal slug 42, two or more of each of the power devices 38 and the thermal slugs 42, and the like).

The power devices 38 and the thermal slugs 42 may be inserted as separate steps, e.g., first the thermal slugs 42 and then power devices 38, or vice versa. Alternately, the power devices 38 and the thermal slugs 42 may be inserted simultaneously. For example, and without limitation, in some variations, the power devices 38 and the thermal slugs 42 may all be supported by a jig, and the jig may be manipulated, e.g., by a robot or other material handling device, to insert all the power devices 38 and the thermal slugs 42 into the first plurality of openings 36 and the second plurality of openings 40 of the dielectric panel 120 in a single operation. The method may include securing the power devices 38 in the first plurality of openings 36 and/or the thermal slugs 42 in the second plurality of openings 40 with an epoxy. For example, and without limitation, in some variations, a two-part epoxy may be filled into any gap spaces surrounding the power devices 38 in the first plurality of openings 36 and/or into any gap spaces surrounding the thermal slugs 42 in the second plurality of openings 40. Additionally or alternately, other materials and/or structures may be used to secure the power devices 38 in the first plurality of openings 36 and/or the thermal slugs 42 in the second plurality of openings 40.

FIG. 4 schematically depicts a method step of securing a multi-layer printed circuit board (PCB) structure 122 to the dielectric panel 120 having the inserted power devices 38 and thermal slugs 42 to form an embedded PCB fabrication panel 124. The multi-layer PCB structure 122 may include semiconductors, control/drive/protection electronic circuitry, passive components, conductive vias, etc., arranged such that the multi-layer PCB structure 122 can be cut or otherwise separated into sections, each of the sections providing a multi-layer PCB 22 of a PCB assembly 20. The multi-layer PCB structure 122 may be secured to the dielectric panel 120 having the inserted power devices 38 and thermal slugs 42 by bonding (e.g., laminating) the multi-layer PCB structure 122 to the dielectric panel 120 having the inserted power devices 38 and thermal slugs 42.

In some variations, bonding the multi-layer PCB structure 122 to the dielectric panel 120 having the inserted power devices 38 and thermal slugs 42 includes bonding or fabricating the multi-layer PCB structure 122 on the dielectric panel 120 having the inserted power devices 38 and thermal slugs 42 layer(s)-by-layer(s). For example, and without limitation, in some variations, bonding of the multi-layer PCB structure 122 to the panel having the inserted power devices 38 and thermal slugs 42 can include bonding a dielectric layer 126 (e.g., an FR4 layer) and a dielectric layer 126 to an upper surface of the dielectric panel 120 having the inserted power devices 38 and thermal slugs 42 as illustrated at Step A in FIG. 4, and drilling vias v into, and at least partially through, the dielectric layer 126 at Step B.

In at least one variation, the vias v extend through the dielectric layer 126 to the dielectric panel 120 having the inserted power devices 38 and thermal slugs 42. For example, and without limitation, in some variations, the vias v can extend through the dielectric layer 126 to a power device 38 or thermal slug 42 of the dielectric panel 120 having the inserted power devices 38 and thermal slugs 42. The vias v are filled with conductive material to form conductive vias v and the conductive layer 128 at Step C and thereby provide interlayer conductive connection(s), and a portion or portions of the conductive layer 128 can be removed at Step D to provide a desired or designed conductive pattern. In addition, Steps A-D, and others (not shown), can be repeated until the multi-layer PCB structure 122 is formed and bonded to the dielectric panel 120 having the inserted power devices 38 and thermal slugs 42 and the embedded PCB fabrication panel 124 is provided. In some variations, the vias are formed or drilled using laser drilling, the vias are filled with conductive material using electroplating (e.g., electroplating of copper into the vias), and/or the portion(s) of the conductive layer is/are removed by etching (e.g., acid etching).

It should be understood that bonding the multi-layer PCB structure 122 to the dielectric panel 120 having the inserted power devices 38 and thermal slugs 42 and forming the embedded PCB fabrication panel 124 before bonding the dielectric panel 120 having the inserted power devices 38 and thermal slugs 42 to a cold plate panel 132 provides electrical communication or pathways between adjacent conductive layers 128 and the power devices 38 without exposing the cold plate panel 132, which may be made from a reactive metal such as aluminum, to a corrosive electroplating solution. Stated differently, fabricating the embedded PCB fabrication panel 124 without the presence of the cold plate panel 132 protects the cold plate panel 132 from being in contact with, and possibly corroded by, an electroplating solution and/or electroplating process.

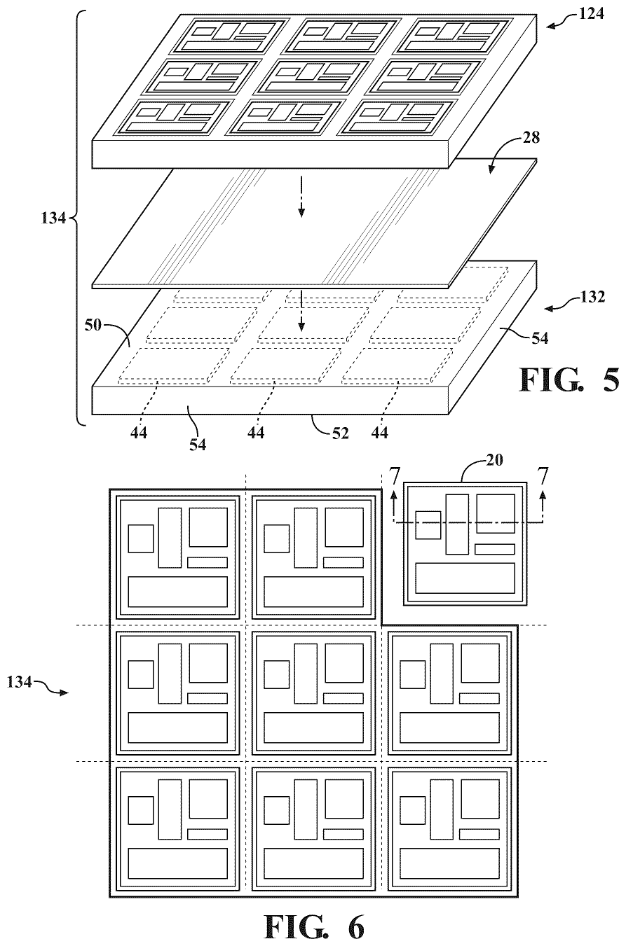

Turning to FIG. 5, a method step of securing the cold plate panel 132 to the embedded PCB fabrication panel 124, e.g., to the dielectric panel 120 opposite the multi-layer PCB structure 122, to form an integrated power electronics fabrication panel 134 is schematically depicted. The cold plate panel 132 may include a plurality of internal fluid chambers 44 arranged such that the cold plate panel 132 can be cut or otherwise separated into sections, each of the sections providing a cold plate 26 of the PCB assembly 20, with each cold plate 26 having an internal fluid chamber 44. For example, and without limitation, each cold plate 26 may have only one internal fluid chamber 44. Each fluid chamber 44 may be defined by the top wall 50, the bottom wall 52, and sidewalls 54 extending from the top wall 50 to the bottom wall 52. The embedded PCB fabrication panel 124 can be bonded to the cold plate panel 132 using any bonding technique or process suitable for bonding a multi-layer PCB 22 to a cold plate 26, including the techniques and processes disclosed herein. And as noted above, in some variations, the embedded PCB fabrication panel 124 is bonded to the cold plate panel 132 via a bonding interface 28 that includes a CVD dielectric layer, a LTR dielectric layer, or a ceramic sintered layer.

In other variations the embedded PCB fabrication panel 124 is bonded to the cold plate panel 132 via the bonding interface 28 using heat (i.e., elevated temperature) and/or pressure (i.e., elevated pressure). For example, in some variations pressures between about 2.1 megapascals (MPa) (300 pounds per square inch (psi)) and about 2.8 MPa (400 psi) are applied to the embedded PCB fabrication panel 124 and the cold plate panel 132 (with the bonding interface 28 sandwiched therebetween). In the alternative, or in addition to, the embedded PCB fabrication panel 124 and the cold plate panel 132, with the bonding interface 28 sandwiched therebetween, are held at temperatures between about 150° C. (300° F.) and about 204° C. (400° F.).

Turning to FIG. 6, a method step of cutting the integrated power electronics fabrication panel 134 into separate single PCB assemblies 20 is schematically depicted. The integrated power electronics fabrication panel 134 can be into separate single PCB assemblies 20, for example, and without limitation, in some variations, with a cutting wheel, band saw, circular saw, or other suitable machining apparatus.

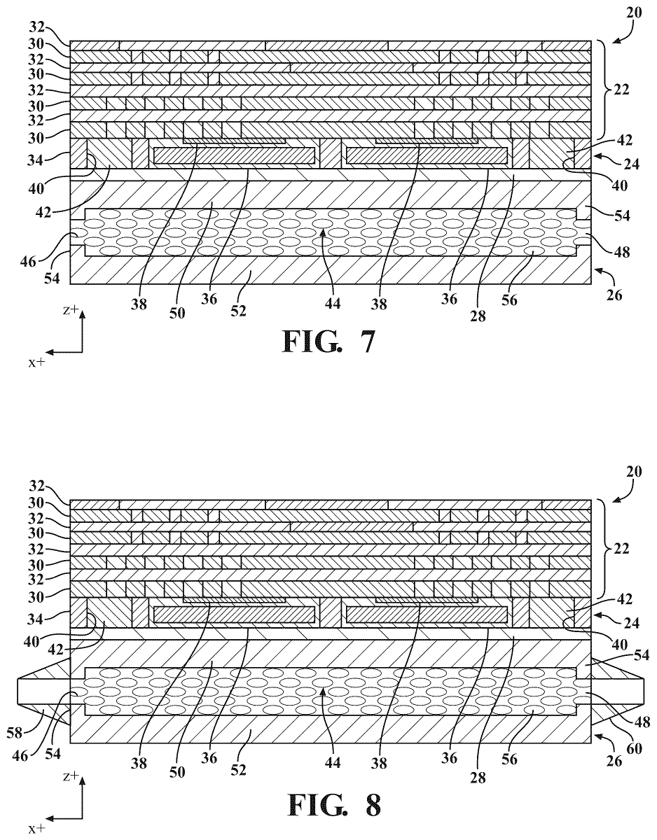

Turning to FIG. 7, a method step of drilling an inlet port 46 and an outlet port 48 into each of the internal fluid chambers 44 is schematically depicted. The inlet port 46 and the outlet port 48 may be drilled using a drill press, multi-axis CNC machine, or other suitable device. The inlet port 46 and the outlet port 48 are shown as drilled into opposing sidewalls 54 of the cold plate 26. Additionally or alternately, the inlet port 46 and/or the outlet port 48 can be drilled into the bottom wall 52 of the cold plate 26 (not shown).

Turning to FIG. 8, a method step of securing an inlet tube 58 to the inlet port 46 and an outlet tube 60 to the outlet port 48 is schematically depicted. The inlet tube 58 and the outlet tube 60 enable fluid lines to be coupled to the cold plate 26. For example, and without limitation, in some variations, a fluid line may be inserted into each of the inlet tube 58 and the outlet tube 60 (not shown). The inlet tube 58 and the outlet tube 60 can be secured with welding, adhesive, or other suitable structure and/or means.

It should now be understood that the embodiments of this disclosure described herein provide increase manufacturing efficiencies and overall reduced costs, e.g., as compared to conventional manufacturing methods. In particular, the increased efficiencies and reduced costs may be provided by attaching, e.g., laminating, the multi-layer PCB structure 122 to the dielectric panel 120 having the power devices 38 and thermal slugs 42 already included therein. Further, the increased efficiencies and reduced costs may be provided by other features of the method and structures described herein.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A method for manufacturing an integrated power electronics (IPEs) embedded printed circuit board (PCB) assembly, the method comprising:
fabricating a dielectric panel that includes a plurality of openings sized and shaped to receive at least one power device and a plurality of thermal slugs, the at least one power device is embedded within the dielectric panel;
laminating a multi-layer printed circuit board on the dielectric panel having the at least one power device embedded within the dielectric panel layer-by-layer, and laser drilling and electroplating layers of the multi-layer printed circuit board to create a plurality of copper vias between the layers;
bonding the dielectric panel and the multi-layer printed circuit board to a cold plate panel to form an integrated power electronics fabrication panel;
cutting or separating the integrated power electronics fabrication panel into a PCB cold plate assembly; and
drilling an inlet port and an outlet port through each cold plate into an internal fluid chamber of the cold plate.

2. The method of claim 1, wherein the dielectric panel is formed of an FR-4 material.

3. The method of claim 1, wherein the thermal slugs are formed of copper material.

4. The method of claim 1, wherein the at least one power device is positioned on a copper-graphite substrate.

5. The method of claim 1, wherein the at least one power device includes a metal-oxide-semiconductor field-effect transistor (MOSFET) or an Insulated-gate bipolar transistor (IGBT).

6. A method for manufacturing an integrated power electronics (IPEs) embedded printed circuit board (PCB) assembly, the method comprising:
providing a dielectric panel having a first plurality of openings configured to receive power devices and a second plurality of openings configured to receive thermal slugs;
inserting power devices into the first plurality of openings and thermal slugs into the second plurality of openings;
securing a multi-layer printed circuit board (PCB) structure to the dielectric panel having the inserted power devices and thermal slugs; and
securing a cold plate panel to the dielectric panel opposite the multi-later PCB structure to form an integrated power electronics fabrication panel.

7. The method of claim 6, wherein the power devices and the thermal slugs are inserted simultaneously.

8. The method of claim 6, further comprising cutting the integrated power electronics fabrication panel into separate single PCB assemblies.

9. The method of claim 8, wherein a cold plate of each of the single PCB assemblies includes an internal fluid chamber.

10. The method of claim 9, wherein each internal fluid chamber includes a heat sink.

11. The method of claim 9, further comprising drilling an inlet port and an outlet port into each of the internal fluid chambers.

12. The method of claim 11, further comprising securing an inlet tube to each of the inlet ports and an outlet tube to each of the outlet ports.

13. The method of claim 6, wherein the thermal slugs are copper.

14. The method of claim 6, wherein the thermal slugs are formed of diamond material.

15. The method of claim 6, further comprising securing the power devices in the first plurality of openings with an epoxy.

16. The method of claim 6, further comprising machining the first plurality of openings and the second plurality of openings in a panel of dielectric material to provide the dielectric panel having the first plurality of openings configured to receive the power devices and the second plurality of openings configured to receive the thermal slugs.

17. A method for manufacturing an integrated power electronics (IPEs) embedded printed circuit board (PCB) assembly, the method comprising:
providing a dielectric panel having a first plurality of openings configured to receive power devices and a second plurality of openings configured to receive thermal slugs;
inserting power devices into the first plurality of openings and thermal slugs into the second plurality of openings, the thermal slugs being formed of diamond material or copper material;
securing a multi-layer printed circuit board (PCB) structure to the dielectric panel having the inserted power devices and thermal slugs;
securing a cold plate panel to the dielectric panel opposite the multi-later PCB structure to form an integrated power electronics fabrication panel; and
cutting the integrated power electronics fabrication panel into separate single PCB assemblies.

18. The method of claim 17, wherein a cold plate of each of the single PCB assemblies includes an internal fluid chamber.

19. The method of claim 18, wherein each internal fluid chamber includes a heat sink.

20. The method of claim 18, further comprising drilling an inlet port and an outlet port into each of the internal fluid chambers.
